(19) United States
(12) Patent Application Publication
(10) Pub. No.: US 2021/0200923 A1
(43) Pub. Date: Jul. 1, 2021

(54) DEVICE AND METHOD FOR PROVIDING A SIMULATION ENVIRONMENT FOR TRAINING AI AGENT

(71) Applicant: ELECTRONICS AND TELECOMMUNICATIONS RESEARCH INSTITUTE, Daejeon (KR)

(72) Inventors: Sihwan JANG, Daejeon (KR); Chan Sub KIM, Daejeon (KR); Seong Il YANG, Daejeon (KR)

(21) Appl. No.: 17/139,216

(22) Filed: Dec. 31, 2020

(30) Foreign Application Priority Data
Dec. 31, 2019 (KR) 10-2019-0179850

(51) Int. Cl. G06F 30/27; G06N 20/00; G06K 9/62

(52) U.S. Cl. CPC G06F 30/27; G06K 9/6232; G06N 20/00

(57) ABSTRACT

Device for simulation environment for training Al agent includes scene object providing module to provide scene and object in virtual content converted from original content; a reward function providing module to provide reward function used by agent to perform reinforcement learning in the virtual content; an environment information providing module to provide virtual environment information including information on environment where the agent performs the reinforcement learning in the virtual content; a status information providing module to provide virtual status information indicating status of the agent in the virtual content; an action space providing module to provide virtual action space indicating action of the agent; and a virtual learning module to create simulation environment based on at least one of the scene, the object, the reward function, the virtual environment information, the virtual status information, and the virtual action space, and perform virtual learning for the agent in the simulation environment.

### CROSS-REFERENCE TO RELATED APPLICATION

This application claims priority to and the benefit of Korean Patent Application No. 10-2019-0179850 filed in the Korean Intellectual Property Office on Dec. 31, 2019, the entire content of which is incorporated herein by reference.

### BACKGROUND OF THE DISCLOSURE

### 1. Field of the Disclosure

The present disclosure relates to a device and a method for providing a simulation environment for training an artificial intelligence agent.

### 2. Description of Related Art

Recently, artificial intelligence agent technology using reinforcement learning and reinforcement learning simulation technology are attracting attention. In this regard, the interest of many researchers is increasing, and research and development continues. Compared to other fields, the game is relatively easy to collect information from an environment and can freely control a reward for an action of an agent, so it is highly utilized as a testbed for solving complex problems in the real world.

However, since the implementation of various scenarios and functions is required to improve user satisfaction, the complexity of the game is also increasing day by day. Therefore, in order to develop an artificial intelligence agent, a lot of resources such as time, cost, and manpower are required. In addition, because reinforcement learning is a method of learning a policy for a status of an agent and an environment to interact, by acquiring a reward through repeated trial and error, if a reward function is incorrectly designed, not only does training agent not work well, but unexpected side effects may occur during the training.

The above information disclosed in this Background section is only for enhancement of understanding of the background of the disclosure, and therefore it may contain information that does not form the prior art that is already known in this country to a person of ordinary skill in the art.

### SUMMARY OF THE DISCLOSURE

The problem to be solved by the present disclosure is to provide a device and a method for providing a simulation environment, which can minimize resources required for artificial intelligence agent development and train an Al agent in an efficient manner.

According to an example embodiment of the present invention, a device for providing a simulation environment is provided. The device includes: a scene object providing module configured to provide a scene and an object used in a virtual content converted from an original content; a reward function providing module configured to provide a reward function used by an agent to perform reinforcement learning in the virtual content; an environment information providing module configured to provide a virtual environment information including an information on an environment in which the agent performs the reinforcement learning in the virtual content; a status information providing module configured to provide a virtual status information indicating a status of the agent in the virtual content; an action space providing module configured to provide a virtual action space indicating an action of the agent in the virtual content; and a virtual learning module configured to create a simulation environment based on at least one of the scene, the object, the reward function, the virtual environment information, the virtual status information, and the virtual action space, and perform virtual learning for the agent in the simulation environment.

The device may further include an agent create module configured to create a virtually learned agent capable of operating on the original content when the virtual learning is completed.

The device may further include an agent control module configured to control the virtually learned agent on the original content.

The device may further include: a graphic simplifying module configured to create the scene and the object from the original content and transmit the scene and the object to the scene object providing module; a reward function create module configured to create the reward function and transmit the reward function to the reward function providing module; and a required information create module configured to create at least one of the virtual environment information, the virtual status information, and the virtual action space and transmit the at least one of the virtual environment information, the virtual status information, and the virtual action space to at least one of the environment information providing module, the status information providing module, and an action space providing module.

The device may further include a requirement extract module configured to extract a requirement necessary for the agent to perform the virtual learning from the original content.

The device may further include a learning objective extract module configured to extract a learning objective used to create the reward function from the original content.

The device may further include an environment information extract module configured to extract an information on an environment for the agent to perform the reinforcement learning from the original content.

The device may further include a status information extract module configured to extract a status information indicating a status of the agent in the original content.

The device may further include an action space extract module configured to extract an action space indicating an action of the agent in the original content.

An amount of information of the virtual content may be less than the amount of information of the original content.

According to another example embodiment of the present invention, a device for providing a simulation environment is provided. The device includes: a graphic simplifying module configured to create a scene and an object used in a virtual content from an original content; a reward function create module configured to create a reward function used by an agent to perform reinforcement learning in the virtual content; a required information create module configured to create at least one of the virtual environment information including an information on an environment in which the agent performs the reinforcement learning in the virtual content, the virtual status information indicating a status of the agent in the virtual content, and the virtual action space indicating an action of the agent in the virtual content.

The device may further include a simulation environment create module configured to create a simulation environment based on at least one of the scene, the object, the reward function, the virtual environment information, the virtual status information, and the virtual action space.

The simulation environment create module may perform virtual learning for the agent in the simulation environment, and create a virtually learned agent capable of operating on the original content when the virtual learning is completed.

The device may further include an agent control module configured to control the virtually learned agent on the original content.

An amount of information of the virtual content may be less than the amount of information of the original content.

According to still another example embodiment of the present invention, a method for providing a simulation environment is provided. The method includes: providing a scene and an object used in a virtual content converted from an original content; providing a reward function used by an agent to perform reinforcement learning in the virtual content; providing a virtual environment information including an information on an environment in which the agent performs the reinforcement learning in the virtual content; providing a virtual status information indicating a status of the agent in the virtual content; providing a virtual action space indicating an action of the agent in the virtual content; and creating a simulation environment based on at least one of the scene, the object, the reward function, the virtual environment information, the virtual status information, and the virtual action space.

The method may further include performing virtual learning for the agent in the simulation environment.

The method may further include creating a virtually learned agent capable of operating on the original content when the virtual learning is completed.

The method may further include controlling the virtually learned agent on the original content. An amount of information of the virtual content may be less than the amount of information of the original content.

According to the embodiments of the present disclosure, after converting an original content into a virtual content with a lower information amount, by using a method of training an agent on the virtual content, and controlling the agent which has completed training in the original content, the resource required for artificial intelligence agent development can be minimized.

In addition, even in a situation where it is difficult to repeat the experiment according to the learning objective in a game in the original content, an artificial intelligence agent can be trained in an efficient manner using the virtual content.

### BRIEF DESCRIPTION OF THE DRAWINGS

FIG. 1 is a block diagram illustrating a device for providing a simulation environment for training an artificial intelligence agent according to an embodiment of the present disclosure.

FIG. 2 is a block diagram illustrating a game content analysis module according to an embodiment of the present disclosure.

FIG. 3 is a block diagram illustrating a heterogeneous environment matching module according to an embodiment of the present disclosure.

FIG. 4 is a block diagram illustrating a simulation environment create module according to an embodiment of the present disclosure.

FIG. 5 is a block diagram illustrating an agent control module according to an embodiment of the present disclosure.

FIG. 6 to FIG. 8 are diagrams for describing a method of providing a simulation environment for training an artificial intelligence agent according to an embodiment of the present disclosure.

FIG. 9 is a block diagram illustrating a computing device implementing a device and a method for providing a simulation environment for training an artificial intelligence agent according to an embodiment of the present disclosure.

### DETAILED DESCRIPTION OF THE EMBODIMENTS

Hereinafter, embodiments of the present disclosure will be described in detail with reference to the accompanying drawings so that those of ordinary skill in the art may easily implement the present disclosure. However, the present disclosure may be implemented in various different ways and is not limited to the embodiments described herein.

In the drawings, parts irrelevant to the description are omitted in order to clearly describe the present disclosure, and like reference numerals are assigned to like elements throughout the specification. Throughout the specification and claims, unless explicitly described to the contrary, the word “comprise”, and variations such as “comprises” or “comprising”, will be understood to imply the inclusion of stated elements but not the exclusion of any other elements. In addition, terms such as “. . . unit”, “. . . group”, and “module” described in the specification mean a unit that processes at least one function or operation, and it can be implemented as hardware or software or a combination of hardware and software.

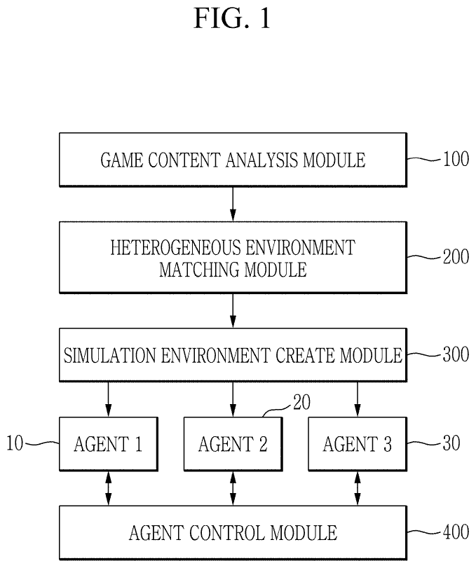

FIG. 1 is a block diagram illustrating a device for providing a simulation environment for training an artificial intelligence agent according to an embodiment of the present disclosure.

Referring to FIG. 1, a device for providing a simulation environment according to an embodiment of the present disclosure may include a game content analysis module 100, a heterogeneous environment matching module 200, a simulation environment create module 300, and an agent control module 400.

The device for providing a simulation environment for training an artificial intelligence agent may be implemented as a computing device. The computing device may be, for example, a smart phone, a smart watch, a smart band, a tablet computer, a notebook computer, a desktop computer, a server, etc., but the scope of the present disclosure is not limited thereto, and may include any type of computer device having a memory and a processor capable of storing and executing computer instructions.

The functions of the device for providing a simulation environment for training an artificial intelligence agent may be implemented on a single computing device, or may be implemented separately on a plurality of computing devices. For example, the plurality of computing devices may include a first computing device and a second computing device, and some functions of the device for providing a simulation environment are implemented on the first computing device, and some other functions of the device for providing a simulation environment are implemented on the second computing device. And, the first computing device and the second computing device may communicate with each other through a network.

Herein, the network includes a wireless network including a cellular network, a Wi-Fi network, a Bluetooth network, a wired network including a local area network (LAN), a wide local area network (WLAN), or a combination of a wireless network and a wired network, but the scope of the present disclosure is not limited thereto.

The device for providing a simulation environment may provide a simulation environment for the agent to perform reinforcement learning. Herein, the simulation environment refers to an environment created by extracting only elements necessary for reinforcement learning (i.e., a virtual environment) from an environment in which the agent actually operates (i.e., a real environment). After performing reinforcement learning in the simulation environment, the agent can operate in the real environment using a trained model when learning is completed.

In the case of a game, the real environment may refer to an original game environment (or an original content), and the virtual environment may refer to a virtual game environment (or a virtual content) created by extracting only elements necessary for reinforcement learning of the agent. Since a virtual content is created by extracting only elements necessary for reinforcement learning from the original content, in general, the amount of information of the virtual content may be less than the amount of information of the original content.

For example, in the original content, game characters, maps, items, and the like are described in detail with high-resolution graphics in order to increase the user's satisfaction, while in the virtual content, game characters, maps, items, and the like may be displayed as relatively simplified figures, shapes, and the like. The agent according to the embodiments of the present disclosure performs reinforcement learning on a virtual content with a small amount of information, and when the learning is completed, it operates in the original content with a large amount of information, thereby minimizing the resources required for artificial intelligence agent development.

In addition, even in situations where it is difficult to repeat the experiment according to the learning objective in the game in the original content, such as when it is difficult to set objectives for reinforcement learning due to complex progression steps in the game, or when it takes a lot of time to learn according to scenarios, an artificial intelligence agent can be trained in an efficient manner using the virtual content.

The game content analysis module 100 may set a situation in which training of an artificial intelligence agent is required from the original content, extract related information about the situation, and provide the extracted information to the heterogeneous environment matching module 200. The information extracted here may include, for example, requirements necessary for reinforcement learning of the agent, learning objectives, environmental information, status information, action space, and the like.

The heterogeneous environment matching module 200 may create information that can be used to create a virtual content from the information provided from the game content analysis module 100, and provide the created information to the simulation environment create module 300. The information created here may include scenes and objects used in a virtual content, reward functions, virtual environment information, virtual status information, virtual action space, and the like.

The simulation environment create module 300 may create a simulation environment from information provided from the heterogeneous environment matching module 200. Specifically, the simulation environment create module 300 may create a simulation environment in which reinforcement learning of the agent can be performed using information such as scenes and objects, reward functions, virtual environment information, virtual status information, and virtual action space and the like, used in virtual content.

In addition, the simulation environment create module 300 may perform reinforcement learning for the agent in the simulation environment, and in this specification, reinforcement learning performed in the simulation environment is referred to as virtual learning. That is, the simulation environment create module 300 may perform virtual learning for the agent in the simulation environment. When the virtual learning is completed, the simulation environment create module 300 may create virtually learned agents 10, 20, and 30 that can operate on the original content.

The agent control module 400 may control agents 10, 20, and 30 virtually learned on the original content. To this end, the agent control module 400 may collect information on the actual (real) environment and status from a server that provides the original content (for example, a game server), and use it to control the virtually learned agents 10, 20, and 30.

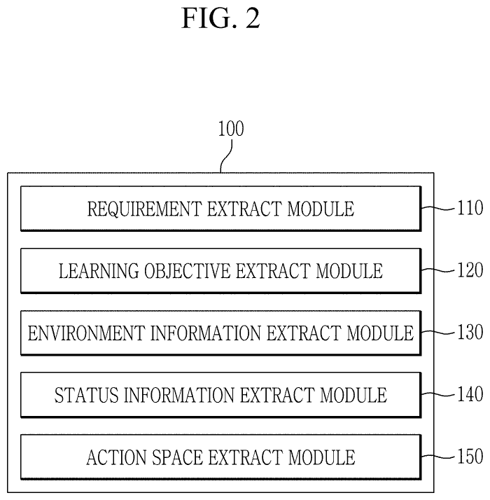

Hereinafter, the game content analysis module 100, the heterogeneous environment matching module 200, the simulation environment create module 300, and the agent control module 400 will be described in detail with reference to FIG. 2 to FIG. 5.

FIG. 2 is a block diagram illustrating a game content analysis module according to an embodiment of the present disclosure.

Referring to FIG. 2, the game content analysis module 100 according to an embodiment of the present disclosure may include a requirement extract module 110, a learning objective extract module 120, an environment information extract module 130, a status information extract module 140, and an action space extract module 150.

The requirement extract module 110 may extract requirements necessary for the agent to perform virtual learning from the original content. Specifically, the requirement extract module 110 may set a situation in which the artificial intelligence agent needs to learn from the original content, and extract the necessary requirements for this, and this may be provided to the graphic simplifying module 210 of the heterogeneous environment matching module 200. Herein, the necessary requirements may refer to a scene or an object that corresponds to a situation that requires learning by an artificial intelligence agent from among several scenes or several objects constituting the game.

The learning objective extract module 120 may extract a learning objective used to create a reward function from the original content. Specifically, the learning objective extract module 120 may extract a learning objective about an item that expects the agent to perform a specific action or behavior from the original content, and this may be provided to the reward function create module 220 of the heterogeneous environment matching module 200.

The environment information extract module 130 may extract an information about an environment for the agent to perform reinforcement learning from the original content. Specifically, the environment information extract module 130 may extract an environment required for reinforcement learning from among environments related to various game situations of the original content, and this may be provided to the required information create module 230 of the heterogeneous environment matching module 200.

The status information extract module 140 may extract a status information indicating the status of the agent in the original content. Specifically, the status information extract module 140 may extract a status required for reinforcement learning from among statuses of the agent related to various game situations of the original content, and this may be provided to the required information create module 230 of the heterogeneous environment matching module 200.

The action space extract module 150 may extract an action space indicating an action of the agent in the original content. Specifically, the action space extract module 150 extracts may an action space required for reinforcement learning from among action spaces of the agent related to various game situations of the original content, and this may be provided to the required information create module 230 of the heterogeneous environment matching module 200.

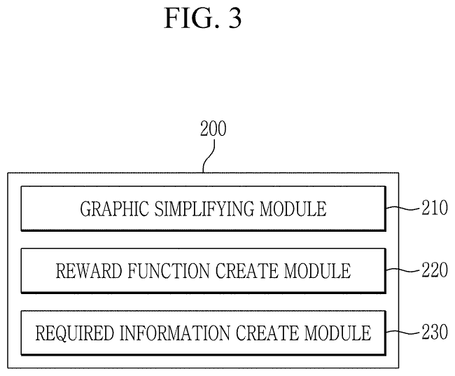

FIG. 3 is a block diagram illustrating a heterogeneous environment matching module according to an embodiment of the present disclosure.

Referring to FIG. 3, the heterogeneous environment matching module 200 according to an embodiment of the present disclosure may include a graphic simplifying module 210, a reward function create module 220, and a required information create module 230.

The graphic simplifying module 210 may create a scene and an object from original content and transmit them to the scene object providing module 310 of the simulation environment create module 300. Specifically, the graphics simplifying module 210 may create a scene and an object used in a virtual content converted from an original content based on the requirements provided from the requirement extract module 110 of the game content analysis module 100.

The reward function create module 220 may create a reward function and transmit it to the reward function providing module 320 of the simulation environment create module 300. Specifically, the reward function create module 220 may create a reward function used by the agent to perform reinforcement learning in a virtual content based on the learning objective provided from the learning objective extract module 120 of the game content analysis module 100.

The required information create module 230 may create at least one of virtual environment information, virtual status information, and virtual action space and transmit at least one of virtual environment information, virtual status information, and virtual action space to at least one of the environment information providing module 330, the status information providing module 340, and the action space providing module 350 of the simulation environment create module 300.

Specifically, the required information create module 230 may create virtual environment information including information about the environment for the agent to perform reinforcement learning in a virtual content based on the environment information provided from the environment information extract module 130 of the game content analysis module 100.

In addition, specifically, the required information create module 230 may create virtual status information indicating a status of the agent in a virtual content based on the status information provided from the environment information extract module 130 of the game content analysis module 100.

In addition, specifically, the required information create module 230 may create virtual action space indicating an action space of the agent in a virtual content based on the action space provided from the environment information extract module 130 of the game content analysis module 100.

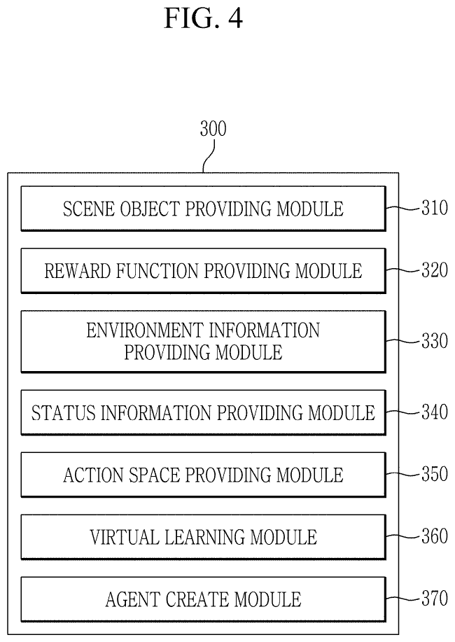

FIG. 4 is a block diagram illustrating a simulation environment create module according to an embodiment of the present disclosure.

Referring to FIG. 4, a simulation environment create module 300 according to an embodiment of the present disclosure may include a scene object providing module 310, a reward function providing module 320, an environment information providing module 330, and status information providing module 340, an action space providing module 350, a virtual learning module 360, and an agent create module 370.

The scene object providing module 310 may provide a scene and an object used in a virtual content converted from an original content. For example, the scene object providing module 310 may provide the scene and the object received from the graphic simplifying module 210 of the heterogeneous environment matching module 200 to the simulation environment create module 300 to create a simulation experiment environment.

The reward function providing module 320 may provide a reward function used by an agent to perform reinforcement learning in the virtual content. For example, the reward function providing module 320 may provide the reward function received from the reward function create module 220 of the heterogeneous environment matching module 200 to the simulation environment create module 300 to create a simulation environment.

The environment information providing module 330 may provide a virtual environment information including an information on an environment in which the agent performs reinforcement learning in the virtual content. For example, the environment information providing module 330 may provide the virtual environment information received from the required information create module 230 of the heterogeneous environment matching module 200 to the simulation environment create module 300 to create a simulation environment.

The status information providing module 340 may provide a virtual status information indicating a status of an agent in virtual content. For example, the status information providing module 340 may provide the virtual status information received from the required information create module 230 of the heterogeneous environment matching module 200 to the simulation environment create module 300 to create a simulation environment.

The action space providing module 350 may provide a virtual action space indicating an action of the agent in virtual content. For example, the action space providing module 350 may provide the virtual action space received from the required information create module 230 of the heterogeneous environment matching module 200 to the simulation environment create module 300 to create a simulation environment.

The virtual learning module 360 may create a simulation environment based on at least one of the scene, the object, the reward function, the virtual environment information, the virtual status information, and the virtual action space, and perform virtual learning for the agent in the simulation environment.

When the virtual learning is completed, the agent create module 370 may created virtually learned agents 10, 20, and 30 capable of operating on the original content. The virtually learned agents 10, 20, and 30 may be controlled by the agent control module 400 in the original content, that is, in an actual (real) game.

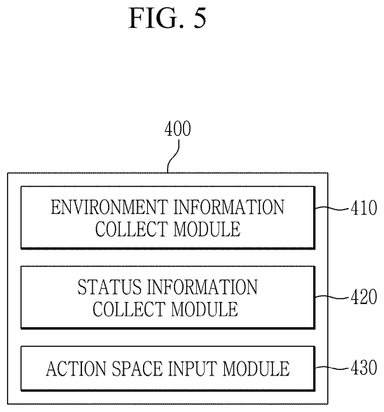

FIG. 5 is a block diagram illustrating an agent control module according to an embodiment of the present disclosure.

Referring to FIG. 5, the agent control module 400 according to an embodiment of the present disclosure may include an environment information collect module 410, a status information collect module 420, and an action space input module 430.

The environment information collect module 410 may collect information on an actual environment, that is, an actual game environment from a server providing original content (e.g., a game server).

The status information collect module 420 may collect information on an actual status, that is, an actual status of an agent, from a server providing original content (e.g., a game server).

The action space input module 430 may use the information collected by at least one of the environment information collect module 410 and the status information collect module 420 to control the virtually learned agents 10, 20, and 30 in the original content, that is, an actual game.

That is, the environmental information collect module 410 and the status information collect module 420 receive the input value of the artificial intelligence agent model from the game server, and the result value obtained by performing an operation on the corresponding value is transmitted to the game server through the action space input module 430 to control the artificial intelligence agent through a model created through virtual learning.

According to an embodiment of the present disclosure, after converting an original content into a virtual content with a lower information amount, by using a method of training an agent on the virtual content, and controlling the agent which has completed training in the original content, the resource required for artificial intelligence agent development can be minimized.

In addition, even in a situation where it is difficult to repeat the experiment according to the learning objective in a game in the original content, an artificial intelligence agent can be trained in an efficient manner using the virtual content.

Each of the modules described so far is merely logically separated and does not represent physically separated. In addition, each of the modules may be implemented by integrating two or more modules into one module or implemented by dividing one module into two or more modules according to a specific implementation purpose or manner.

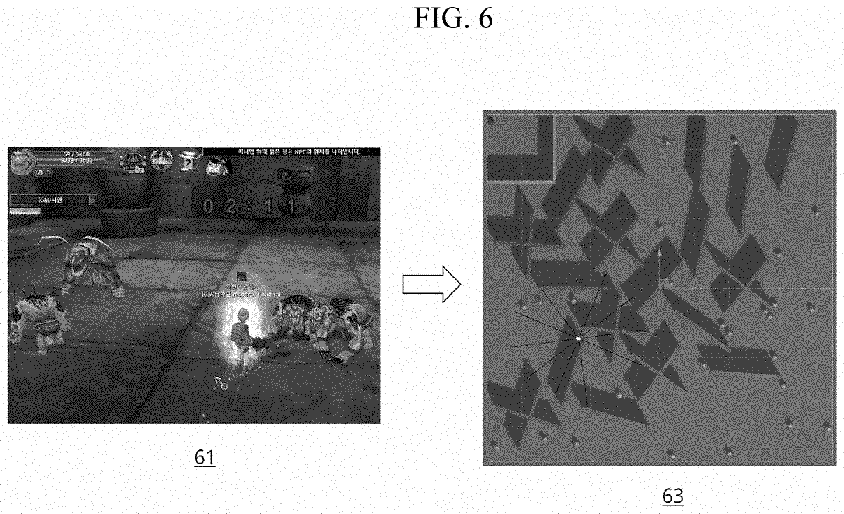

FIG. 6 to FIG. 8 are diagrams for describing a method of providing a simulation environment for training an artificial intelligence agent according to an embodiment of the present disclosure.

A method of providing a simulation environment according to an embodiment of the present disclosure includes: providing a scene and an object used in a virtual content converted from an original content; providing a reward function used by an agent to perform reinforcement learning in the virtual content; providing a virtual environment information including an information on an environment in which the agent performs the reinforcement learning in the virtual content; providing a virtual status information indicating a status of the agent in the virtual content; providing a virtual action space indicating an action of the agent in the virtual content; and creating a simulation environment based on at least one of the scene, the object, the reward function, the virtual environment information, the virtual status information, and the virtual action space.

For more detail about this, the above description may be referred to with reference to FIG. 1 to FIG. 5, so a description of this will be omitted herein.

Referring to FIG. 6, a picture 61 shows a situation of an instance dungeon in a game of the role-playing genre. In the functions and scenarios where the player enters and moves within the instance dungeon, kills monsters, the monster appears when a certain number of monsters are killed, and the mission is accomplished when the boss monster is defeated, scenes and objects created through the graphic simplifying module 210 of the heterogeneous environment matching module 200 may be expressed as shown in the picture 63.

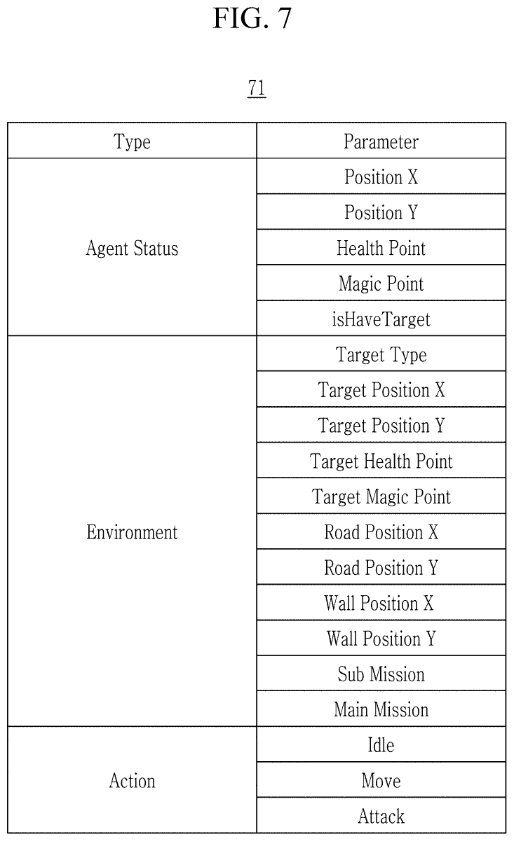

Next, referring to FIG. 7, the required information create module 230 of the heterogeneous environment matching module 200 may create virtual environment information, virtual status information, and virtual action space as shown in FIG. 7.

For example, the virtual environment information may include parameters related to the target type, the target position, the target health point, the target magic point, the road position, the wall position, missions to be performed, etc., but these specific details may vary depending on the specific implementation purpose.

In addition, the virtual status information may include parameters related to the position of the agent, the health point, the magic point, relationship or interaction with the target, and the like, and these specific details may vary depending on specific implementation purposes.

In addition, the virtual action space may include parameters related to idle, move, attack, etc., in relation to the actions of the agent, and these specific details may vary depending on specific implementation purposes.

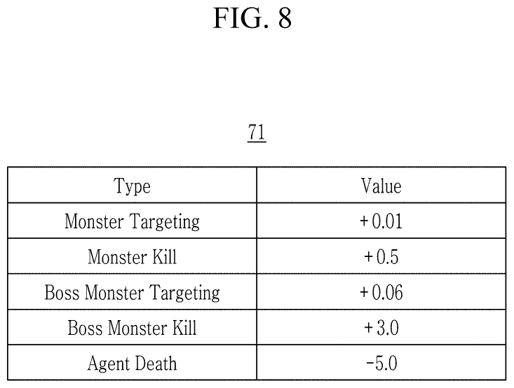

Next, referring to FIG. 8, the reward function create module 220 of the heterogeneous environment matching module 200 may create a learning policy as illustrated in FIG. 8.

For example, the learning policy can define rewards for targeting monsters, killing monsters, targeting boss monsters, killing boss monsters, and agent dead, etc., and these specific details may vary depending on specific implementation purposes.

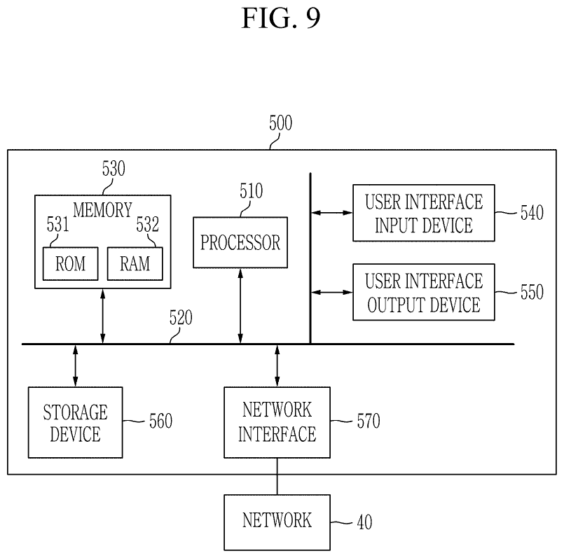

FIG. 9 is a block diagram illustrating a computing device implementing a device and a method for providing a simulation environment for training an artificial intelligence agent according to an embodiment of the present disclosure.

Referring to FIG. 9, a device and a method for providing a simulation environment according to an embodiment of the present disclosure may be implemented using the computing device 50.

The computing device 50 includes at least one of a processor 510, a memory 530, a user interface input device 540, a user interface output device 550, and a storage device 560 communicating through a bus 520. The computing device 50 may also include a network 40, such as a network interface 570 that is electrically connected to a wireless network. The network interface 570 may transmit or receive signals with other entities through the network 40.

The processor 510 may be implemented in various types such as an application processor (AP), a central processing unit (CPU), and a graphic processing unit (GPU), and may be any semiconductor device which executes instructions stored in the memory 530 or the storage device 560. The processor 510 may be configured to implement the functions and methods described in FIG. 1 to FIG. 8.

The memory 530 and the storage device 560 may include various types of volatile or nonvolatile storage media. For example, the memory may include read-only memory (ROM) 531 and random access memory (RAM) 532. In an embodiment of the present disclosure, the memory 530 may be located inside or outside the processor 510, and the memory 530 may be connected to the processor 510 through various known means.

In addition, at least some of a device and a method for providing a simulation environment according to embodiments of the present disclosure may be implemented as a program or software executed on the computing device 50, and the program or software may be stored in a computer-readable medium.

In addition, at least some of a device and a method for providing a simulation environment according to embodiments of the present disclosure may be implemented with hardware that can be electrically connected to the computing device 50.

According to the embodiments of the present disclosure described so far, after converting an original content into a virtual content with a lower information amount, by using a method of training an agent on the virtual content, and controlling the agent which has completed training in the original content, the resource required for artificial intelligence agent development can be minimized.

In addition, even in a situation where it is difficult to repeat the experiment according to the learning objective in a game in the original content, an artificial intelligence agent can be trained in an efficient manner using the virtual content.

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

What is claimed is:

1. A device for providing a simulation environment, comprising:
a scene object providing module configured to provide a scene and an object used in a virtual content converted from an original content;
a reward function providing module configured to provide a reward function used by an agent to perform reinforcement learning in the virtual content;
an environment information providing module configured to provide a virtual environment information including an information on an environment in which the agent performs the reinforcement learning in the virtual content;
a status information providing module configured to provide a virtual status information indicating a status of the agent in the virtual content;
an action space providing module configured to provide a virtual action space indicating an action of the agent in the virtual content; and
a virtual learning module configured to create a simulation environment based on at least one of the scene, the object, the reward function, the virtual environment information, the virtual status information, and the virtual action space, and perform virtual learning for the agent in the simulation environment.

2. The device of claim 1, further comprising:
an agent create module configured to create a virtually learned agent capable of operating on the original content when the virtual learning is completed.

3. The device of claim 2, further comprising:
an agent control module configured to control the virtually learned agent on the original content.

4. The device of claim 1, further comprising:
a graphic simplifying module configured to create the scene and the object from the original content and transmit the scene and the object to the scene object providing module;
a reward function create module configured to create the reward function and transmit the reward function to the reward function providing module; and
a required information create module configured to create at least one of the virtual environment information, the virtual status information, and the virtual action space and transmit the at least one of the virtual environment information, the virtual status information, and the virtual action space to at least one of the environment information providing module, the status information providing module, and an action space providing module.

5. The device of claim 1, further comprising:
a requirement extract module configured to extract a requirement necessary for the agent to perform the virtual learning from the original content.

6. The device of claim 1, further comprising:
a learning objective extract module configured to extract a learning objective used to create the reward function from the original content.

7. The device of claim 1, further comprising:
an environment information extract module configured to extract an information on an environment for the agent to perform the reinforcement learning from the original content.

8. The device of claim 1, further comprising:
a status information extract module configured to extract a status information indicating a status of the agent in the original content.

9. The device of claim 1, further comprising:
an action space extract module configured to extract an action space indicating an action of the agent in the original content.

10. The device of claim 1, wherein:
an amount of information of the virtual content is less than the amount of information of the original content.

11. A device for providing a simulation environment, comprising:
a graphic simplifying module configured to create a scene and an object used in a virtual content from an original content;
a reward function create module configured to create a reward function used by an agent to perform reinforcement learning in the virtual content;
a required information create module configured to create at least one of the virtual environment information including an information on an environment in which the agent performs the reinforcement learning in the virtual content, the virtual status information indicating a status of the agent in the virtual content, and the virtual action space indicating an action of the agent in the virtual content.

12. The device of claim 11, further comprising:
a simulation environment create module configured to create a simulation environment based on at least one of the scene, the object, the reward function, the virtual environment information, the virtual status information, and the virtual action space.

13. The device of claim 12, wherein:
the simulation environment create module performs virtual learning for the agent in the simulation environment, and creates a virtually learned agent capable of operating on the original content when the virtual learning is completed.

14. The device of claim 13, further comprising:
an agent control module configured to control the virtually learned agent on the original content.

15. The device of claim 11, wherein:
an amount of information of the virtual content is less than the amount of information of the original content.

16. A method for providing a simulation environment, comprising:
providing a scene and an object used in a virtual content converted from an original content;
providing a reward function used by an agent to perform reinforcement learning in the virtual content;
providing a virtual environment information including an information on an environment in which the agent performs the reinforcement learning in the virtual content;
providing a virtual status information indicating a status of the agent in the virtual content;
providing a virtual action space indicating an action of the agent in the virtual content; and
creating a simulation environment based on at least one of the scene, the object, the reward function, the virtual environment information, the virtual status information, and the virtual action space.

17. The method of claim 16, further comprising:
performing virtual learning for the agent in the simulation environment.

18. The method of claim 17, further comprising:
creating a virtually learned agent capable of operating on the original content when the virtual learning is completed.

19. The method of claim 18, further comprising:
controlling the virtually learned agent on the original content.

20. The method of claim 16, wherein:
an amount of information of the virtual content is less than the amount of information of the original content.
